(19) United States
(12) Patent Application Publication
(10) Pub. No.: US 2010/0302614 A1
(43) Pub. Date: Dec. 2, 2010

(54) MEMS AND ELECTROPHORETIC DISPLAY DEVICES INTEGRATED WITH ORGANIC LIGHT-EMITTING DEVICE

(75) Inventors: Du-Zen Peng, Hsinchu County (TW); Ryuji Nishikawa, Hsinchu City (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: CHIMEI INNOLUX CORPORATION, Miao-Li County (TW)

(21) Appl. No.: 12/783,631

(22) Filed: May 20, 2010

(30) Foreign Application Priority Data
May 26, 2009 (TW) 98117409

(51) Int. Cl. G02F 1/167; G02B 26/02

(52) U.S. Cl. 359/230; 359/296

(57) ABSTRACT

A system for displaying images is provided. The system includes a display device including a first substrate having a pixel unit array thereon. A second substrate is disposed above the first substrate. A plurality of micro-electro-mechanical system shutters is disposed between the first substrate and the second substrate and corresponds to each pixel unit of the pixel unit array. An organic light-emitting device is disposed between the second substrate and the plurality of micro-electro-mechanical system shutters to serve as a light source of the display device. A system for displaying images including a display device with an electrophoretic display layer is also disclosed.

This Application claims priority of Taiwan Patent Application No. 098117409, filed on May 26, 2009, the entirety of which is incorporated by reference herein.

### BACKGROUND OF THE INVENTION

1. Field of the Invention

The invention relates to flat panel displays (FPD), and in particular to a micro-electro-mechanical system (MEMS) and electrophoretic display devices integrated with a front light device.

2. Description of the Related Art

FPD devices are widely employed in electronic products, such as portable personal computers, personal digital assistants (PDAs), electronic books, projectors, mobile phones, and the like, due to their thin profiles, light weights and low power consumption when compared to conventional cathode ray tube (CRT) display devices. Such a FPD device includes a liquid crystal display (LCD) device, an organic light-emitting display (OLED) device, a MEMS display device, and an electrophoretic display (EPD) device.

In these FPD devices, the LCD, MEMS, and EPD devices are non self-emissive type display device that needs an additional backlight or front light module to serves as a light source for displaying images. The MEMS device, however, has advantages of high switching speed, contrast, and optical efficiency compared to the LCD device, and therefore can be applied to data projectors and high definition TVs. Additionally, the EPD device has advantages of low power consumption, good flexibility, and good readability and therefore can be applied to paper-like displays, such as electronic books.

Since an additional front/back light module is still required for MEMS and EPD display devices, it is difficult to reduce total display thickness and weight thereof. Thus, with the progress of electronic applications, such display thickness and weight cannot meet the current demands. Accordingly, there exists a need in the art for development of an improved display device, capable of reducing total display thickness and weight.

### BRIEF SUMMARY OF THE INVENTION

A detailed description is given in the following embodiments with reference to the accompanying drawings. Systems for displaying images are provided. An exemplary embodiment of a system for displaying images comprises a display device comprising a first substrate having a pixel unit array thereon. A second substrate is disposed above the first substrate. A plurality of micro-electro-mechanical system shutters is disposed between the first substrate and the second substrate and corresponds to each pixel unit of the pixel unit array. An organic light-emitting device is disposed between the second substrate and the plurality of micro-electro-mechanical system shutters to serve as a light source of the display device.

Another exemplary embodiment of a system for displaying images comprises a display device including a first substrate having a pixel unit array thereon. A second substrate is disposed above the first substrate. An electrophoretic display layer is disposed between the first substrate and the second substrate. An organic light-emitting device disposed between the second substrate and the electrophoretic display layer to serve as a light source of the display device.

### BRIEF DESCRIPTION OF DRAWINGS

The invention can be more fully understood by reading the subsequent detailed description and examples with references made to the accompanying drawings, wherein:

FIG. 1 is a cross section of an embodiment of a system for displaying images including a MEMS display device according to the invention;

FIG. 2 is an enlarged view of a pixel unit shown in FIG. 1;

FIG. 3 is a cross section of another embodiment of a system for displaying images including an EPD device according to the invention; and

FIG. 4 schematically shows another embodiment of a system for displaying images.

### DETAILED DESCRIPTION OF INVENTION

The following description is of the best-contemplated mode of carrying out the invention. This description is provided for the purpose of illustrating the general principles of the invention and should not be taken in a limiting sense. The scope of the invention is best determined by reference to the appended claims.

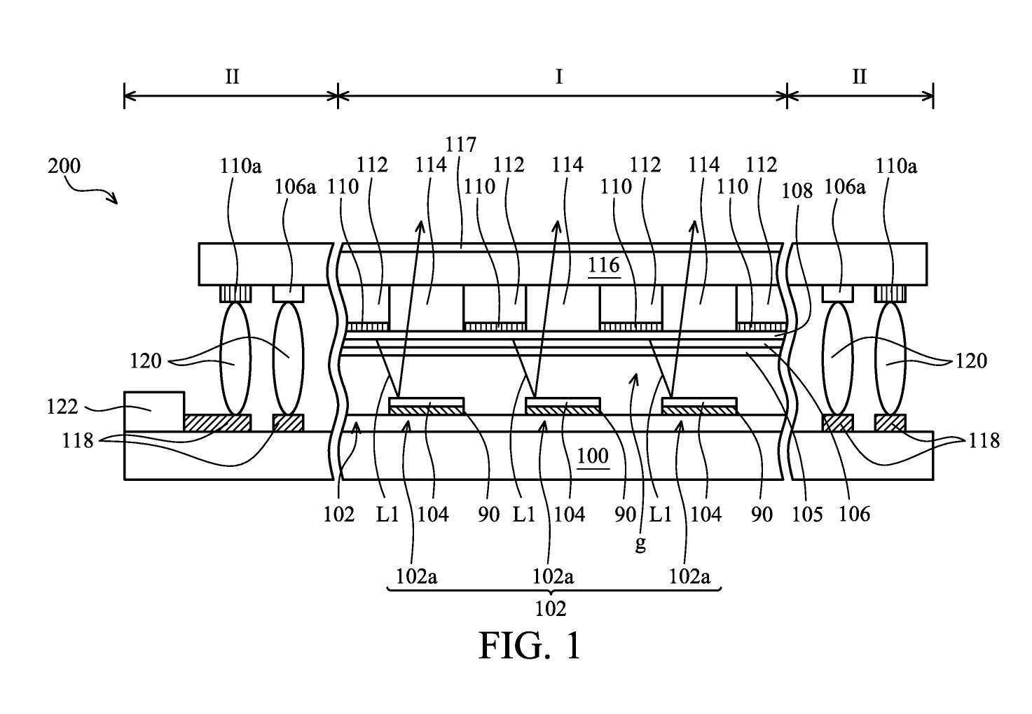

Systems for displaying images are provided. Referring to FIG. 1, which is a cross section of an embodiment of a display device 200 according to the invention. In the embodiment, the display device 200 is a MEMS display device and comprises a first substrate 100, a second substrate 116, a plurality of MEMS shutters 104, and a light-emitting device serving as a front light source.

The first substrate 100 has a display region I and non-display regions II, and may comprise glass, quartz, or other transparent materials. A pixel unit array 102 is on the first substrate 100 and located at the display region I. A plurality of metal distribution lines 118 and a flexible printed circuit (FPC) 122 electrically connected thereto are on the first substrate 100 and located at the non-display regions II.

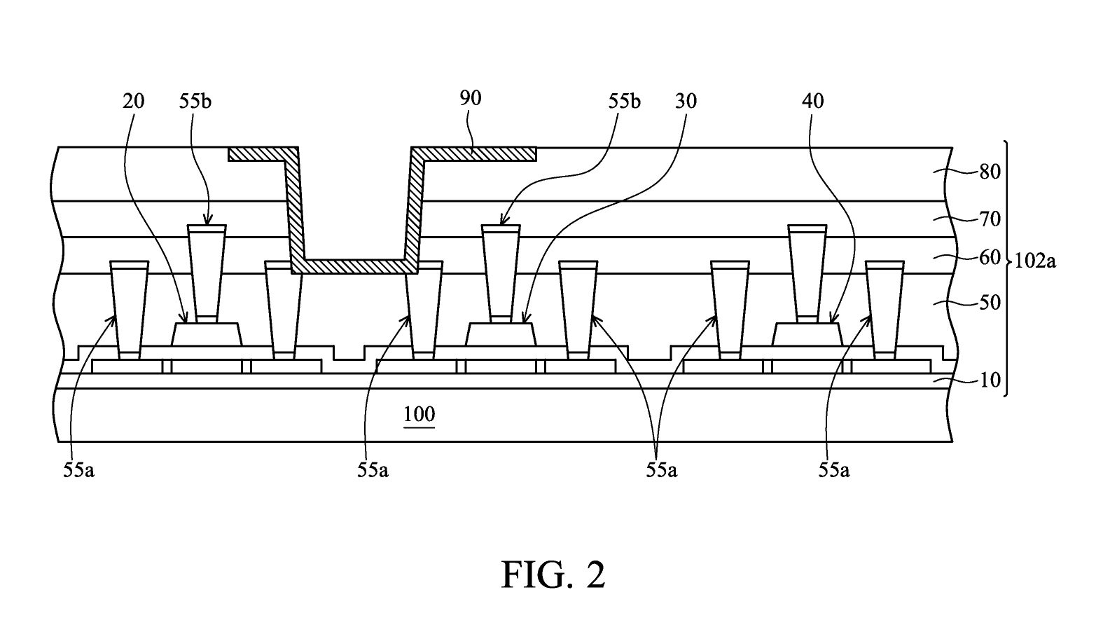

Referring to FIG. 2, which illustrates an enlarged view of a pixel unit 102a shown in FIG. 1. In one embodiment, a pixel unit 102a may comprise three thin film transistors (TFTs) 20, 30, and 40. The TFTs 20, 30, and 40 are usually adhered onto the first substrate 100 by a buffer layer 10. A first intervening layer 50, a second intervening layer 60, a third intervening layer 70, and a protective layer 80 are successively stacked on the TFTs 20, 30, and 40. Moreover, the TFTs 20, 30, and 40 are electrically connected to a scan line (not shown) and a data line (not shown) by conductive plugs 55a and 55b formed in the first, second, and third intervening layers 50, 60, and 70. A pixel electrode 90 is disposed on the protective layer 80 and may comprise an opaque reflective material, such as metal. In some embodiments, the pixel electrode 90 may comprise an opaque reflective material and a transparent material such as indium tin oxide (ITO). Moreover, the pixel electrode 90 is electrically connected to the TFTs 20 and 30 by the conductive plugs 55a.

The second substrate 116 may also comprise glass, quartz, or other transparent materials. In the embodiment, a color filter array 114 may be disposed on the second substrate 116 and correspondingly face to the pixel unit array 102 on the first substrate 100. A black matrix (BM) 112 is also disposed on a surface of the second substrate 116 and between the color filters of the color filter array 114. The surface of the black matrix 112 adjacent to the second substrate 116 has a reflective index less than 20% and the black matrix 112 may comprise chromium oxide, chromium nitride, titanium nitride, molybdenum nitride, or resin. In another embodiment, the color filter array may be correspondingly disposed on the pixel unit array 102 on the first substrate 100.

A first electrode distribution line 110a and a second electrode distribution line 106a are disposed on the second substrate 116 and correspond to the non-display region II, thereby electrically connecting to the different metal distribution lines 118 on the first substrate 100. In one embodiment, the first electrode distribution line 110a and the second electrode distribution line 106a are electrically connected to the metal distribution lines 118 by metal pastes 120. In another embodiment, the first electrode distribution line 110a and the second electrode distribution line 106a are electrically connected to the metal distribution lines 118 by anisotropic conductive films (ACF) (not shown).

The plurality of MEMS shutters 104 is disposed between the first substrate 100 and the second substrate 116, and corresponds to each pixel unit 102a of the pixel unit array 102. The light-emitting device may be disposed above the first substrate 100 to serve as a light source of the display device 200 (i.e. MEMS display device) during actuating the plurality of MEMS shutters 104.

The light-emitting device may comprise a plurality of first electrodes 110, a second electrode 106, and an organic light emissive layer 108. The plurality of first electrodes 110 is disposed between the black matrix 112 and the first substrate 100 and corresponds to each MEMS shutter 104. In the embodiment, the plurality of first electrodes 110 serves as an anode of the light-emitting device and is electrically connected to the first electrode distribution line 110a. The plurality of first electrodes 110 and the first electrode distribution line 110a may be formed by the same conductive layer that comprises ITO or indium zinc oxide (IZO). In one embodiment, each first electrode 110 has a reflective index greater than 70% and comprises aluminum, argentum, chromium, titanium, molybdenum, an alloy thereof, or a combination thereof. Accordingly, the plurality of first electrodes 110 can be used as the black matrix. The second electrode 106 serves as a cathode of the light-emitting device, and is disposed between the plurality of first electrodes 110 and the plurality of MEMS shutters 104, and is electrically connected to the second electrode distribution line 106a. Also, the second electrode 106 and the second electrode distribution line 106a may be formed by the same conductive layer that comprises ITO or IZO. The organic light emissive layer 108 is disposed between the plurality of first electrodes 110 and the second electrode 106. In some embodiments, the single organic light emissive layer 108 (i.e. a non-patterned organic light emissive layer) can be replaced by a plurality of organic light emissive patterned layers (not shown) corresponding to the plurality of first electrodes 110.

Each MEMS shutter 104 can be used as an electrode of a MEMS device, such as an interferometric modulator. Typically, the interferometric modulator includes a pair of electrodes capable of relative motion by applying an appropriate electrical signal thereto. One of the pair of electrodes is a stationary electrode, and the other one is a movable electrode separated from the stationary electrode by an air gap g. The interferometric modulator refers to a display device that selectively absorbs and/or reflects light using the principle of optical interference. In the embodiment, each MEMS shutter 104 serves as a moveable electrode. In particular, the second electrode 106 of the display device may also serve as a common electrode that actuates the plurality of MEMS shutters 104.

An insulating layer 105 is disposed between the second electrode 106 and the plurality of MEMS shutters 104 to serve as a protective layer of the display device 200. The insulating layer 105 may comprise silicon nitride, silicon oxynitride, polyimide (PI), or a combination thereof.

Additionally, an optical film 117, such as a polarizer, an anti-reflection film, or an anti-glare film, is optionally adhered onto the surface of the second substrate 116 corresponded to the display region I and faces to the view sides of the display device 200.

According to this embodiment, since an organic light-emitting device is used as a light source for the display device 200, the weight of the display can be reduced when compared to other type display devices using a front light module as a light source. Moreover, since the organic light-emitting device is disposed between the two substrates of the MEMS display device and since one of the electrodes of the organic light-emitting device is used as a common electrode of the MEMS device, the total display thickness can be reduced and manufacturing costs can be saved when compared to the conventional display device where the front light module is disposed outside of the two substrates of the display device.

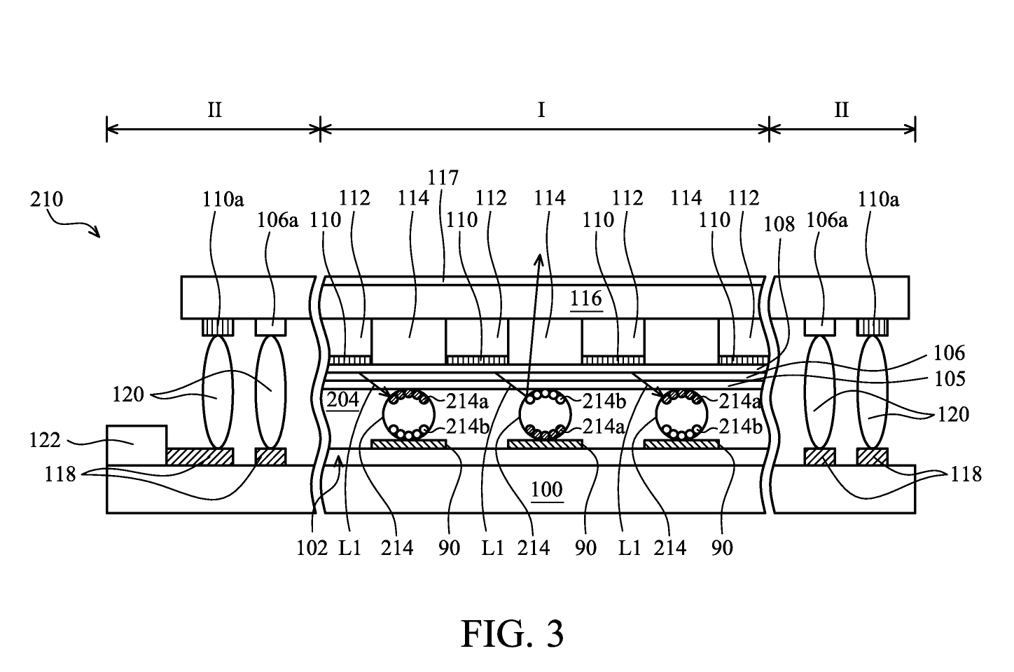

Referring to FIG. 3, which illustrates another embodiment of a system for displaying images including a display device 210 according to the invention. Elements in FIG. 3 that are the same as those in FIG. 1 are labeled with the same reference numbers as in FIG. 1 and are not described again for brevity. In the embodiment, the display device 210 is an EPD device having a structure similar as that of the MEMS display device shown in FIG. 1. The difference in this embodiment is that an electrophoretic display layer 204 is disposed between the first substrate 100 and the second substrate 116 instead of the plurality of MEMS shutters 104.

The electrophoretic display layer 204 typically comprises a binder and a plurality of polymer microcapsules 214 spread therein. Each polymer microcapsules 214 includes a solvent made of, for example, isopropyl alcohol (IPA) therein. There are black particles 214a with nano-level size and white particles 214b with nano-level size in the solvent. Generally, white particles 214b have a negatively charged polarity and black particles 214a have a postively charged polarity. In one embodiment, when a positive voltage is applied to the pixel electrode 90, a large amount of the white particles 214b are attracted by the pixel electrode 90 and gathered close to the pixel electrode 90, and a large amount of the black particles 214a are repelled by the pixel electrode 90 and gathered close to the second electrode 106 of the light-emitting device, as the right and left polymer microcapsules 214 shown in FIG. 3. As a result, a light L1 provided from the light-emitting device is absorbed by the black particles 214a. When a negative voltage is applied to the pixel electrode 90, a large amount of the white particles 214b are repelled by the pixel electrode 90 and gathered close to the second electrode 106 of the light-emitting device, and a large amount of the black particles 214a are attracted by the pixel electrode 90 and gathered close to the pixel electrode 90, as the middle polymer microcapsules 214 shown in FIG. 3. As a result, the light L1 provided from the light-emitting device is reflected to the outside of the display device 210 by the white particles 214b for display. Also, the second electrode 106 of the light-emitting device serves as a common electrode that controls the electrophoretic display layer 204.

According to this embodiment, since an organic light-emitting device is used as a light source for the display device 210, the weight of the display can be reduced when compared to other type display devices using a front light module as a light source. Moreover, since the organic light-emitting device is disposed between the two substrates of the EPD device and since one of the electrodes of the organic light-emitting device is used as a common electrode for the electrophoretic display layer, the total display thickness can be reduced and manufacturing costs can be saved when compared to the conventional display device where the front light module is disposed outside of the two substrates of the display device.

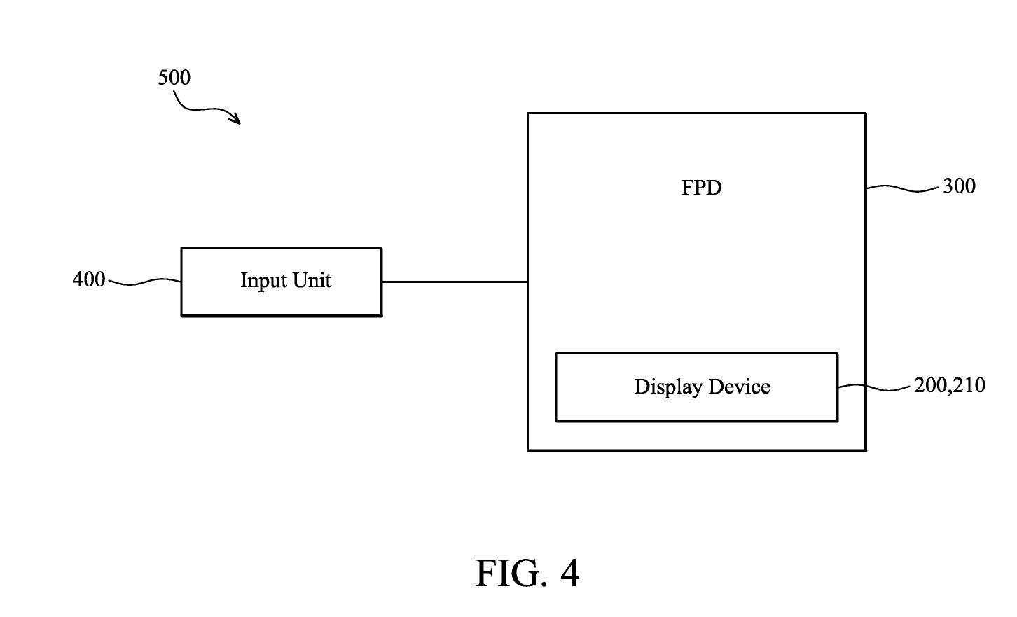

FIG. 4 schematically shows another embodiment of a system for displaying images which, in this case, is implemented as a flat panel display (FPD) 300 or an electronic device 500 such as a projector, an electronic book, a laptop computer, a mobile phone, a digital camera, a personal digital assistant (PDA), a desktop computer, a television, a car display or a portable DVD player. The described display devices 200 and 210 can be incorporated into the FPD 300 which can be an MEMS display or EPD. In some embodiments, the display device 200 can be incorporated into the electronic device 500. As shown in FIG. 4, the electronic device 500 comprises the FPD 300 and an input unit 400. Moreover, the input unit 400 is coupled to the FPD 300 and is operative to provide input signals (e.g. image signals) to the FPD 300 to generate images.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A system for displaying images, comprising:
a display device, comprising:
a first substrate having a pixel unit array thereon;
a second substrate disposed above the first substrate;
a plurality of micro-electro-mechanical system shutters disposed between the first substrate and the second substrate and corresponding to each pixel unit of the pixel unit array; and
an organic light-emitting device disposed between the second substrate and the plurality of micro-electro-mechanical system shutters to serve as a light source of the display device.

2. The system of claim 1, wherein the organic light-emitting device comprises:
a plurality of first electrodes corresponding to the plurality of micro-electro-mechanical system shutters;
a second electrode disposed between the plurality of first electrodes and the plurality of micro-electro-mechanical system shutters to serve as a common electrode that actuates the plurality of micro-electro-mechanical system shutters; and
an organic light-emissive layer disposed between the plurality of first electrodes and the second electrode.

3. The system of claim 2, wherein the second substrate has a color filter array thereon corresponding to the pixel unit array, and has a black matrix disposed between color filters of the color filter array.

4. The system of claim 2, wherein the display device further comprises an insulating layer disposed between the second electrode and the plurality of micro-electro-mechanical system shutters.

5. The system of claim 1, wherein the display device further comprises an optical layer adhered to the surface of the second substrate.

6. The system of claim 1, wherein the second substrate has a first electrode distribution line and a second electrode distribution line, and the first substrate has a plurality of metal distribution lines and a flexible printed circuit electrically connected thereto.

7. The system of claim 6, wherein the first electrode distribution line and the second electrode distribution line are electrically connected to different metal distribution lines by metal pastes or anisotropic conductive films.

8. The system as claimed in claim 1, further comprising:
a flat panel display comprising the display device; and
an input unit coupled to the flat panel display and operative to provide input singles to the flat panel display, such that the flat panel display displays images.

9. The system of claim 8, wherein the system comprises an electronic device comprising the flat panel display.

10. The system of claim 9, wherein the electronic device is a projector, an electronic book, a laptop computer, a mobile phone, a digital camera, a personal digital assistant, a desktop computer, a television, a car display or a portable DVD player.

11. A system for displaying images, comprising,
a display device, comprising:
a first substrate having a pixel unit array thereon;
a second substrate disposed above the first substrate;
an electrophoretic display layer disposed between the first substrate and the second substrate; and
an organic light-emitting device disposed between the second substrate and the electrophoretic display layer to serve as a light source of the display device.

12. The system of claim 11, wherein the organic light-emitting device comprises:
a plurality of first electrodes corresponding to each pixel unit of the pixel unit array;
a second electrode disposed between the plurality of first electrodes and the electrophoretic display layer to serve as a common electrode that controls the electrophoretic display layer; and
an organic light-emissive layer disposed between the plurality of first electrodes and the second electrode.

13. The system of claim 12, wherein the second substrate has a color filter array thereon corresponding to the pixel unit array, and has a black matrix disposed between color filters of the color filter array.

14. The system of claim 12, wherein the display device further comprises an insulating layer disposed between the second electrode and the electrophoretic display layer.

15. The system of claim 11, wherein the display device further comprises an optical layer adhered to the surface of the second substrate.

16. The system of claim 11, wherein the second substrate has a first electrode distribution line and a second electrode distribution line, and the first substrate has a plurality of metal distribution lines and a flexible printed circuit electrically connected thereto.

17. The system of claim 16, wherein the first electrode distribution line and the second electrode distribution line are electrically connected to different metal distribution lines by metal pastes or anisotropic conductive films.

18. The system as claimed in claim 11, further comprising:
a flat panel display comprising the display device; and
an input unit coupled to the flat panel display and operative to provide input singles to the flat panel display, such that the flat panel display displays images.

19. The system of claim 18, wherein the system comprises an electronic device comprising the flat panel display.

20. The system of claim 19, wherein the electronic device is a projector, an electronic book, a laptop computer, a mobile phone, a digital camera, a personal digital assistant, a desktop computer, a television, a car display or a portable DVD player.
